(19) United States
(12) Patent Application Publication
(10) Pub. No.: US 2025/0151418 A1
(43) Pub. Date: May 8, 2025

(54) DOUBLE-SIDED PHOTOVOLTAIC (PV) PANEL AND METHOD OF MANUFACTURING

(71) Applicant: PURE IMPACT FZCO, Dubai (AE)

(72) Inventor: Huseyin Cenk YABAS, Dubai (AE)

(21) Appl. No.: 18/836,768

(22) PCT Filed: Feb. 9, 2022
(86) PCT No.: PCT/IB2022/051157

§ 371 Date: Aug. 8, 2024

(51) Int. Cl. H10F 19/80; H01L 23/373; H10F 19/40

(52) U.S. Cl. CPC H10F 19/807; H01L 23/3736; H10F 19/40

(57) ABSTRACT

There is disclosed a double-sided photovoltaic (PV) panel comprising a central thermal layer; and at least two independent solar cell arrays attached on both sides of the central thermal layer, and each of the at least two independent solar cell arrays being covered by a protection layer; wherein the central thermal layer, the at least two independent solar cell arrays, and the glass protection layers are sandwiched together to form the double-sided PV panel. Also disclosed is a method of manufacturing the double-sided PV panel. The double-sided PV panel further comprises a central support structure and a surrounding frame, the surrounding frame comprising a plurality of connectors to enable water circulation through the cooling pipe, wherein the water circulation enabling cooling down of accumulated heat present on the double-sided PV panel during operation, and thereby eliminating formation of cracks or hotspots on the double-sided PV panel.

### FIELD OF THE INVENTION

The present invention relates to the field of solar panels or photovoltaic (PV) panels, and more particularly to a double-sided PV panel for increased electrical efficiency.

### BACKGROUND OF THE INVENTION

Background description includes information that may be useful in understanding the present invention. It is not an admission that any of the information provided herein is prior art or relevant to the presently claimed invention, or that any publication specifically or implicitly referenced is prior art.

Traditionally implemented solar or photovoltaic (PV) panels include a single solar cell and sandwich the solar cell in between glass panels, with an aim to capture light from both sides of the PV panel (and thereby for optimizing output of the PV panel). However, the main drawbacks faced by traditionally implemented solar panels or systems involve the solar or PV panels being capable of capturing solar rays in specific angles or directions only, and the remaining incident solar rays go uncaptured, and thereby wasted. This leads to low electrical efficiency of the implemented PV system or panels (in other words, systems employing traditional PV panels face huge electrical losses).

Shading losses are another major defect which affects performance efficiency of solar panels. Whenever a cell or panel does not receive sunlight due to a shaded obstruction, it lowers the amount of electricity generated by that solar section. This is what is known as PV system shade loss. Such obstructions can come from a variety of sources such as nearby objects, trees, antennas or poles. As a result, power output of the panel will be reduced proportionally to the area that is shaded. Solar efficacy is also determined by the season, wherein in hotter seasons more electricity than required is generated, while in colder seasons insufficient amounts of electricity is generated. Also, solar panels will undergo deterioration from ultra-violet rays in addition to foreign particles such as matter blown by wind, hail, snow, dirt and temperature fluctuations are also serious threats to solar panels.

Durability is another major issue faced by traditional solar panels, as cracks very easily develop on panels installed especially on rooftops which adversely affects performance and life of the panels. Further, generation of hotspots add to or rather speed up the degradation of solar cells. When current flows through the solar cell strings within panels, the resistance in cells converts the current into heat losses and any imperfection in solar cells, such as cracks, poorly soldered joints, and mismatches, lead to higher resistance and become hot spots in the long run. Long term effects of hot spots include burnt marks that degrade solar cells and backsheets and may eventually lead to fires if left unchecked.

Accordingly, there exists a need for a PV panel design, which overcomes drawbacks of traditionally employed panel designs and/or systems.

### SUMMARY OF THE INVENTION

Therefore it is an object of the present invention to propose a PV panel design, which overcomes drawbacks of traditionally employed panels designs and/or systems.

There is disclosed a double-sided photovoltaic (PV) panel comprising a central thermal layer; and at least two independent solar cell arrays attached on both sides of the central thermal layer, and each of the at least two independent solar cell arrays being covered by a protection layer; wherein the central thermal layer, the at least two independent solar cell arrays, and the glass protection layers are sandwiched together to form the double-sided photovoltaic (PV) panel.

In an embodiment of the present invention, the double sided PV panel is a single structure with a thickness of less than 5 mm.

In an embodiment of the present invention, each of the at least two independent solar cell arrays is encapsulated in a film of EVA (ethylene-vinyl acetate).

In an embodiment of the present invention, the protection layer is a glass layer, anti-reflective and made of tempered low iron glass.

In an embodiment of the present invention, a thickness of the glass layer is in between 2 to 3.2 mm.

In another embodiment of the present invention, the central thermal layer is an aluminium sheet or backing plate, for absorbing heat accumulated in the at least two independent solar cell arrays.

In another embodiment of the present invention, the central thermal layer comprises at least two aluminium sheets or backing plates.

In another embodiment of the present invention, the aluminium sheet or backing plate is coated with a dark shaded paint or an absorption assisting paint.

In an embodiment of the present invention, the double-sided PV panel further comprises a central support structure and a surrounding frame for supporting the double-sided PV panel.

In an embodiment of the present invention, the central support structure and the surrounding frame are made of aluminium.

In another embodiment of the present invention, movement or a tilt angle of the double-sided PV panel installed on the central support structure and the surrounding frame is controllable in real-time, for capturing direct solar rays and/or diffused light at all times and in all seasons.

In an embodiment of the present invention, the central support structure is configured to be installed on a rooftop.

In an embodiment of the present invention, a cooling pipe is located within the central thermal layer.

In another embodiment of the present invention, the surrounding frame further comprises a plurality of connectors to enable water circulation through the cooling pipe, wherein the water circulation enabling cooling down of accumulated heat present on the double-sided PV panel during operation, and thereby eliminating formation of cracks or hotspots on the double-sided PV panel.

In an embodiment of the present invention, the cooling pipe is made of copper.

In an embodiment of the present invention, individual solar cells of the at least two independent solar cell arrays are sliced and connected as shingled solar cells partly overlapping each other.

As another aspect of the present invention, a method of manufacturing a double-sided photovoltaic (PV) panel is disclosed, the method comprising the steps of encapsulating a first and a second solar cell array each in between films of EVA (ethylene-vinyl acetate); installing a thermal layer on an inner portion of the first and second solar cell arrays; providing a protection layer on an outer or externally facing portion of the first and second solar cell arrays and sandwiching together the first and second solar cell arrays, the thermal layer and the protection layer to form the double sided PV panel.

In an embodiment of the present invention, a vacuum press is used for sandwiching together the first and second solar cell arrays, the backing plate and the glass layers.

In an embodiment of the present invention, the said method further comprises installing the double-sided PV panel on a central support structure and a surrounding frame for supporting the double-sided PV panel during operation.

As another aspect of the present invention, a method of operating a double sided PV panel is disclosed, the method comprising the steps of providing a double sided panel manufactured as stated above, wherein movement or a tilt angle of the double-sided PV panel is controllable in real-time, for capturing direct solar rays and/or diffused light at all times and in all seasons.

In an embodiment of the present invention, the double-sided PV panel is kept flat or at an 180° position in colder periods to keep warm an interior of a construction on which the double-sided PV panel is installed.

In an embodiment of the present invention, the colder periods comprise nighttime, days when less sunlight is available and cold seasons.

### BRIEF DESCRIPTION OF THE DRAWINGS

The subject matter that is regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIGS. 1 and 2 illustrate the proposed double-sided PV panel or thermo-cogeneration panel, in accordance with the present invention.

FIG. 3 shows a direction of the flow of electricity across the double-sided solar panel, in accordance with the present invention.

FIGS. 4A and 4B illustrate a central support structure of the double-sided PV panel or thermo-cogeneration panel, in accordance with the present invention.

FIGS. 5A and 5B show the proposed double-sided PV structure with aluminium support structures and in connection with copper piping, in accordance with the present invention.

FIG. 6 depicts an example of water flowing through the copper piping in accordance with the present invention.

FIG. 7 is a depiction of the movement/tilting operation of the proposed double-sided PV panel or thermo-cogeneration panel, in accordance with the present invention.

### DETAILED DESCRIPTION OF THE INVENTION

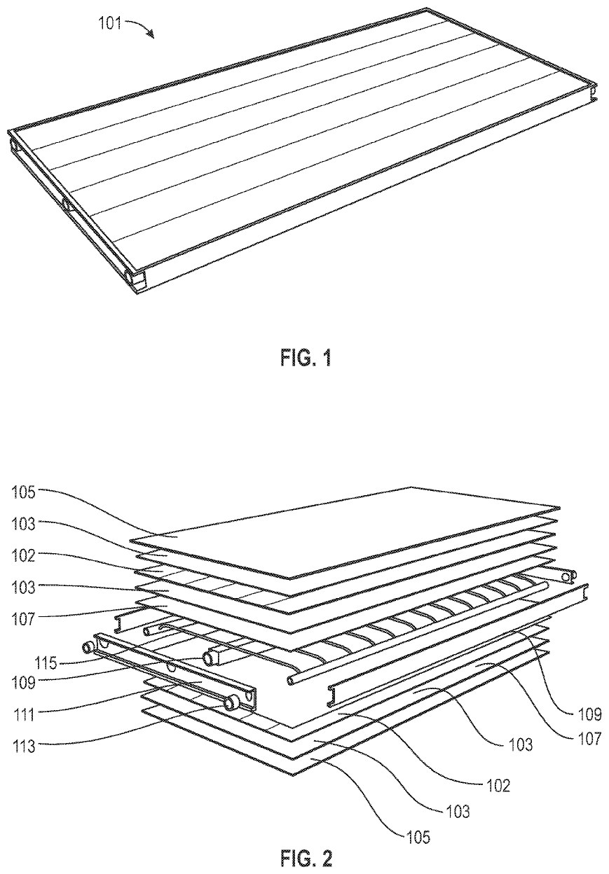

The aspects of the proposed double-sided PV panel design and structure, according to the present invention will be described in conjunction with FIGS. 1-7. In the Detailed Description, reference is made to the accompanying figures, which form a part hereof, and in which is shown by way of illustration specific embodiments in which the invention may be practiced. It is to be understood that other embodiments may be utilized and logical changes may be made without departing from the scope of the present invention. The following detailed description, therefore, is not to be taken in a limiting sense, and the scope of the present invention is defined by the appended claims.

The present invention discloses a double-sided photovoltaic (PV) panel (solar cell panel, solar electric panel or photo-voltaic module) 101 with a thermal layer 107 in between or a ‘thermo-cogeneration panel’, for achieving electrical efficiency. The main drawbacks faced by traditionally implemented solar panels or systems involve the solar or PV panels being capable of capturing solar rays in specific angles or directions only, and the remaining incident solar rays go uncaptured, and thereby wasted. This leads to low electrical efficiency of the implemented PV system or panels (in other words, systems employing traditional PV panels face huge electrical losses). Accordingly, an objective of the present invention is to propose a double-sided PV panel comprising a thermal layer in between the double-sided panel, for achieving electrical efficiency. The proposed PV panel enables capturing solar rays incident from any and all directions, during any time of the day and in all seasons—for achieving maximum electrical efficiency and an optimum daily light integral (DLI) value. The proposed PV panels may be placed tilted on the roofs of buildings, nethouses used for growing crops or plants or on an indoor farming or vertical farming construction.

A tilt angle of the proposed double-sided PV panel or thermo-cogeneration panel is automatically adjusted in real-time (complete control), based on various factors such as a particular season (summer, winter or rainy), a type of crop being cultivated (such as, but not limited to, vegetables, fruits, creepers, flowering plants or leafy greens) and time of the day. Traditionally implemented solar or PV panels include a single solar cell and sandwich the solar cell in between glass panels, with an aim to capture light from both sides of the PV panel (and thereby for optimizing output of the PV panel).

The proposed double-sided PV panel or thermo-cogeneration panel 101, as depicted in FIGS. 1 and 2—comprises two independent solar or PV cell arrays 102 welded together back to back, along with EVA (ethylene-vinyl acetate, also known as poly (ethylene-vinyl acetate) (PEVA), the copolymer of ethylene and vinyl acetate) film layers 103 and a protective layer or glass layer 105 additionally welded on outer sides of the proposed double-sided PV panel 101. Hence, there exists at least two independent solar cell arrays sandwiched together. The EVA film layers 103 act as encapsulating layers or films for the two solar cell arrays 102. In other words, a double-sided photovoltaic (PV) panel 101 comprising a central thermal layer 107; and at least two independent solar cell arrays 102 attached on both sides of the central thermal layer 107, and each of the at least two independent solar cell arrays 102 being covered by a protection layer 105; wherein the central thermal layer 107, the at least two independent solar cell arrays 102, and the glass protection layers 105 are sandwiched together to form the double-sided PV panel 101.

The outer glass layer 105 is anti-reflective and a low riding glass layer with high transparency properties. In an embodiment of the present invention, the glass layer 105 comprises tempered low iron glass with an anti-reflective coating. A thickness of the said glass layer 105 is 3.2 mm. The central thermal layer 107 of the double-sided PV panel 101 is an innermost backing plate or sheet painted with an absorption coating, the main functionality of which is to preserve or hold heat in this central portion of the double-sided PV panel 101. In an embodiment of the present invention, this backing plate 107 is an aluminium sheet painted with a relatively dark or black coloured paint—and is capable of holding approximately 98% of the incident heat, including the amount of heat which is conveyed or passes through the PV panel 101. In another embodiment of the present invention, the central thermal layer comprises at least two aluminium sheets or backing plates.

Further elaborating on the double-sided arrangement in accordance with the present invention, a first solar cell array 102a is encapsulated in between a pair of EVA layers or films 103a, and further covered using a protection layer 105a on the upper or external portion of the solar panel 102a, and covered using the thermal layer or backing plate 107a on the lower or internal portion of the solar array 102a. A mirrored arrangement of the above structure comprises a second solar cell array 102b, which is encapsulated in between a pair of EVA layers or films 103b, and further covered using a protection layer 105b on the external portion of the solar array 102b, and covered using the thermal or backing plate 107b on the internal portion of the solar array 102b. All of the above described layers are subsequently assembled together to form a single double-sided PV panel 101, in accordance with the present invention. The various layers are welded together using a vacuum press, and the EVA layers or sheets 103 being thermoplastic materials—assists in gluing together the various layers together, as a single layer or structure, which is less than 5 mm in thickness (all layers put together).

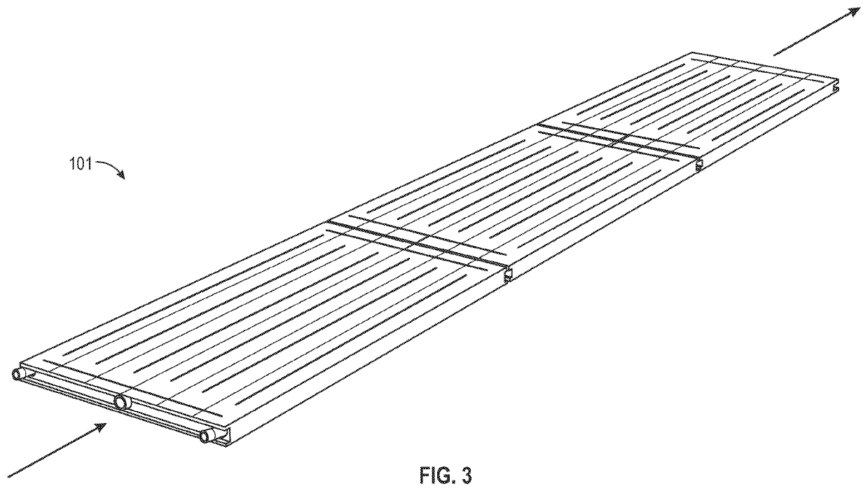

FIG. 3 shows a direction of the flow of electricity across the double-sided solar panel 101. The plurality of solar cell arrays are connected in parallel, and the multiple solar panels 101 being connected in series (considering a constant current value and increasing voltage values).

A method of manufacturing the PV panel or thermo-cogeneration panel is also proposed in the present invention. The method comprises the steps of encapsulating a first and a second solar cell array (102a and 102b) each in between films of EVA (ethylene-vinyl acetate)—103a and 103b; installing a thermal layer (107a and 107b) on an inner portion of the first and second solar cell arrays (102a and 102b); providing a protection layer (105a and 105b) on an outer or externally facing portion of the first and second solar cell arrays (102a and 102b) and sandwiching together the first and second solar cell arrays (102a and 102b), the thermal layer (107a and 107b) and the protection layers (105a and 105b) to form the double sided PV panel 101. A vacuum press is used for sandwiching together the first and second solar cell arrays (102a and 102b), the thermal layer (107a and 107b) and the protection layers (105a and 105b).

The double-sided solar panel 101 is installed or fixed solely along a central portion, as it is desired to keep a back portion of the double-sided solar panel 101 non-obstructed. In accordance with the present invention, all sides of the proposed double-sided PV panel 101 are clear from any obstructions or barriers to collect any reflected light as well as diffused light from the incident solar rays.

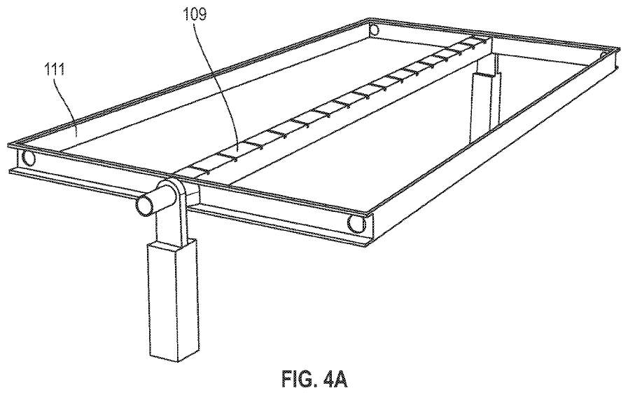

In an embodiment of the present invention, the double-sided PV panel 101 further comprises a central support structure 109 and a surrounding frame 111 for supporting the double-sided PV panel 101 and the central support structure 109 and the surrounding frame 111 are made of aluminium. Accordingly, as depicted in FIGS. 4A and 4B, the double-sided PV panel or thermo-cogeneration panel 101 further comprises a central support structure 109, preferably made of aluminium, along with a surrounding aluminium frame 111 connected along four corners only. As can be seen from FIG. 4, the central support structure 109 and surrounding aluminium frame 111 allows for the double-sided solar panel 101 to be fixed and well-supported on the support structure, without obstructing either of the sides (102a and 102b) of the double-sided solar panel 101. In another embodiment of the present invention, the surrounding frame further comprises a plurality of connectors 113 (present on all four corners of the surrounding frame 111) to enable water circulation through the cooling pipe, wherein the water circulation enabling cooling down of accumulated heat present on the double-sided PV panel during operation, and thereby eliminating formation of cracks or hotspots on the double-sided PV panel.

Another functionality of the connectors 113 are to enable a cooling pipe or copper pipe 115 to be installed or welded to the said pipe connectors 113 as well as to the backing plates 107a and 107b. The cooling pipe 115 is located within the central thermal layer 107.

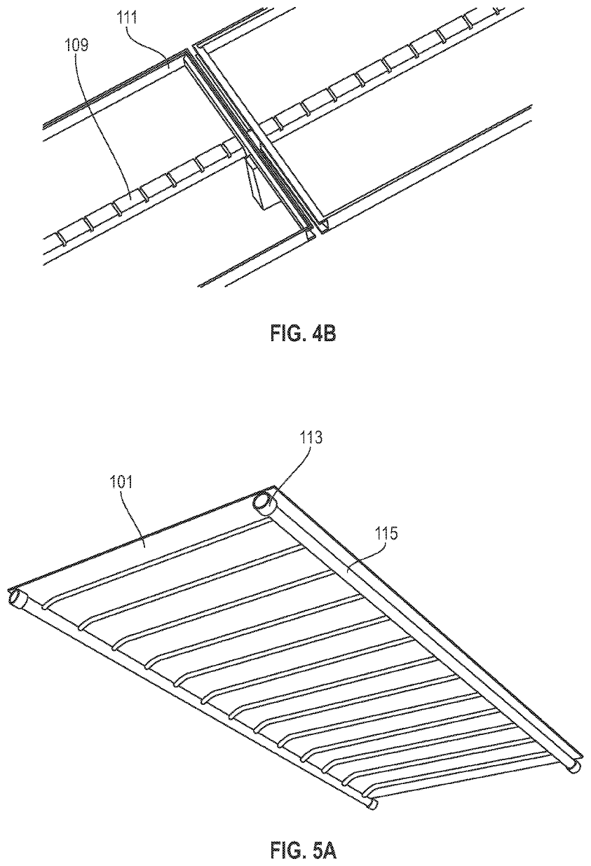

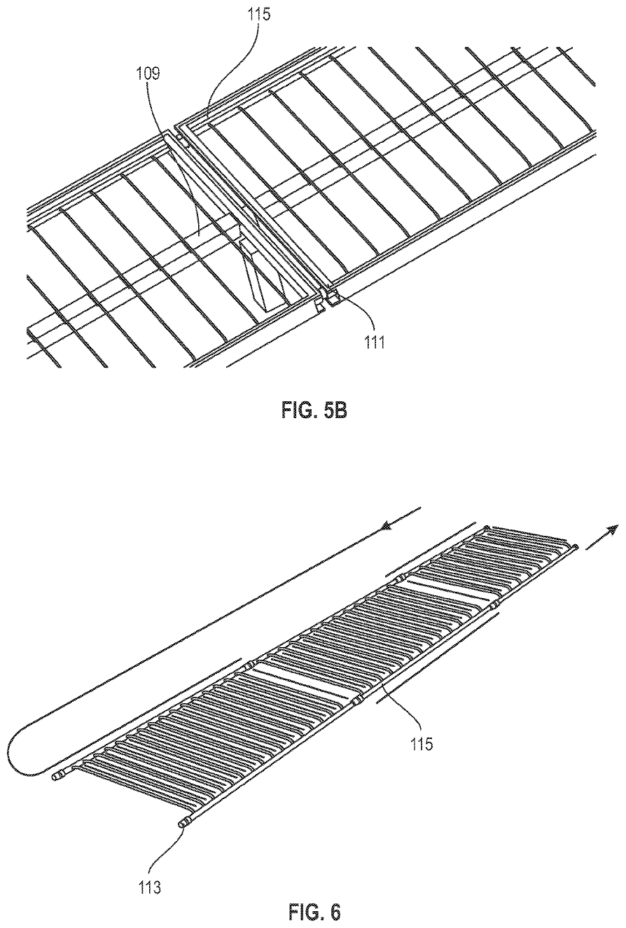

As shown in FIGS. 5A and 5B, the proposed double-sided PV structure 101 comprises aluminium support structures (109 and 111) and is in connection with copper piping 115. The copper piping 115 is welded to the backing plates 107, as well as to the aluminium support structures (109 and 111). Also, considering the structure of the aluminium support structures (109 and 111), results in zero shading losses for the proposed PV panel 101—as these are in no way a barrier or obstruction to both or all faces of the said PV panel 101. The functionality of the copper pipes 115 is to act as a cooling pipe, wherein water (cool) is allowed to enter through a first side of the pipes 115 and this water flows and exits through the other side of the pipes (as hot water) after absorbing heat generated on the panels, or vice-versa (input and output ends of the copper pipes 115 are interchangeable). FIG. 6 depicts an example of water flowing through the copper piping 115 in accordance with the present invention (wherein water flows parallel to the current, thereby increasing overall efficiency), and the copper piping 115 thereby functioning as a heat collector for the proposed PV panel 101. The cooling pipe 115 is in the form of a ladder with multiple steps or multiple branches which connect two main bordering pipe-lines, and this structure also allows for the cooling pipe to sit properly on multiple grooves present on the central support 109. In an embodiment of the present invention, the central support structure 109 is configured to be installed on a rooftop.

The advantage of using the copper piping as a cooling pipe (or heat collector) enables the PV panel to be kept cool at all times, and to avoid over heating of the installed PV panel 101. The copper pipes 115 comprises gaps in between and also functions as a support structure or frame for the proposed PV panel 101. As a result of multiple support structures (109 and 111) and connectors 113 for the PV panel 101 enables the proposed double-sided PV panel 101 to be moved or tilted in any angle during operation—with an aim to capture incident solar rays at any time of the day. The structural support structures in accordance with the present invention are thin and lightweight frame structures. In an embodiment, the surrounding aluminium frame 111 has a thickness of 4 cm. The structural support for the PV panel comprising the surrounding aluminium frame 111 along with an additional central support 109 enhances strength and durability of the said structural support.

Also, based on a color of the floor or platform on which the PV panels are installed, the overall electricity produced may be increased up to 30%. For example, if the floor or platform on which the proposed PV panels 101 are installed is white in color.

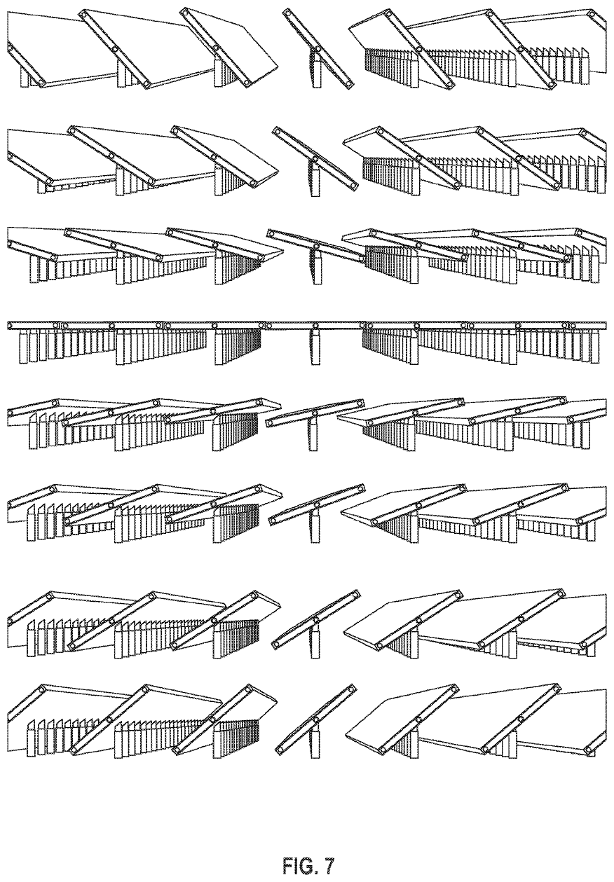

In an embodiment of the present invention, the proposed PV panels positioned on the support structure, in a way wherein the PV panels may be automatically tilted or moved during the course of operation to capture solar rays incident from any direction, is installed preferably on rooftops of buildings or any such construction. The advantage of this proposed structure is the capability to capture solar rays during the day time—direct sunlight and also diffused solar rays from either sides of the PV panel (equal amounts of diffusion), whereas during the night or when there is low availability of solar rays (for example, during winter), the PV panels may be moved to a 180° position or kept flat on the rooftops to keep the interior of the building or construction warm. A depiction of this movement/tilting operation is depicted in FIG. 7. The various positions and movement range of the proposed double-sided PV panels 101 are depicted as multiple stages. In other words, a movement or a tilt angle of the double-sided PV panel installed on the central support structure and the surrounding frame is controllable in real-time, for capturing direct solar rays and/or diffused light at all times and in all seasons.

The proposed arrangement of the double-sided PV panels on rooftops enables maximum protection during adverse climates, and the flexibility and ease of tilting the panels makes it easier to brush off any accumulated dust or impurities from the panels. Accordingly, PV plus thermal co-generation panels harvest up to 88% of solar energy. Considering an application of the proposed PV panels 101 wherein the PV panels (capable of movement at all times) are installed on the rooftop of an indoor farming building for example an vertical farming arrangement. The design of the proposed PV panel 101 may be tweaked to suit the type of crop or vegetable being harvested and depending on the season, to optimize overall costs and efficiency of the implemented structure.

In another embodiment of the present invention, the individual solar cells of the solar cell arrays 102 are implemented as a shingled solar cell array. Ribbons (flexible glue ribbons) are welded and connected from top to a bottom portion of each of the individual cells, which are cut into individual slices (and shingled). An advantage of such a connection is flexibility and durability of the solar cell arrays (avoid cracks for a considerable duration of time). Considering the case with traditionally implemented solar panels, one of the main reasons these start losing efficiency is lack of durability, and another reason being that each individual solar cell (silicon-based) provide 0.5-0.6V each, and hence to reach a required voltage numerous such cells need to placed back to back. For example, on an experimental basis—72 solar cells were installed in a 1×1 m panel, and connected serially. The, 22 or 33 panels (each comprising 72 solar cells) were connected serially in order to reach a desired voltage of 1000-1500 V. The main risk encountered in such situations is shading. When a single panel is partially shaded, this leads to the entire panel being shut down owing to a diode which was cut automatically. This is because if a panel is shaded partially, it becomes a hot spot rather than becoming cold—until it burns out. Hence, if you have a dead point, the system needs to be shortcut.

In order to avoid such losses, the solar cells are sliced and shingled in the present invention, resulting in approximately 5 times more voltage in a single line. In other words, individual solar cells of the at least two independent solar cell arrays 102 are sliced and connected as shingled solar cells partly overlapping each other.

Hence, in this case, the solar cells are connected in parallel and the panels connected in series. Hence, no diodes are needed if there is partial shading and in case partial shading occurs, no dead points are created (also eliminating the need for short circuiting). Even if one panel is being shaded, there is another panel located nearby which captures the solar rays. In seasons like summer and spring when the solar rays are more and intense, more number of panels are implemented on the rooftops, to capture full light and in winter these panels may be flipped to allow passage of all the incident light and to absorb diffusion light. The use of shingle type solar panels, improves overall efficiency (loss of energy is minimized in relation to shading). Another advantage of using shingled solar panels is that overall power loss is linear and a loss in a single cell will not affect performance and efficiency of the whole solar panel. Hence, the proposed thermal or thermo-cogeneration solar panels in the system not only harvest heat but also optimizes electrical efficiency.

In another embodiment of the present invention, light emitting diodes (LEDs) installed in a vertical farming system on which the proposed double-sided PV panels are installed—are also adjusted (or connections altered) in accordance with the season. Lesser shadows are needed during the winter season and more shadows are desired during the summer season (thereby increasing produced electricity for the vertical farming system). Further, LEDs installed in the vertical farming system are also adjusted as per the season to ensure yield during all seasons. During those months when a targeted daily light integral (DLI) value is not met, alternative crops which have lower DLI requirements are selected to be cultivated—to ensure yield during all seasons. Another step taken to maximize photovoltaic and thermal productivity of the PV panels is to keep the PV panels flat on the rooftops—to double the electrical productivity, termed as ‘Building integrated PV panels’ for direct and diffused solar rays. In other words, in conditions wherein available daylight or solar rays are minimum, the PV panels are moved to lay flat on the rooftops, in order to capture every bit of available solar rays, and the resulting solar energy is split to be used for powering the LEDs in the building, as well as to warm the interior of the building. In this way wastage of the available minimum amount of incident solar rays is also avoided.

In another embodiment of the present invention, movement or a tilt angle of the double-sided PV panel 101 installed on the central support structure 109 and surrounding frame 111 is controllable in real-time, for capturing direct solar rays and/or diffused light at all times and in all seasons. The double-sided PV panel is kept flat or at an 180° position in colder periods to keep warm an interior of a construction on which the double-sided PV panel is installed, the colder periods including night-time, days when less sunlight is available and cold seasons.

Many changes, modifications, variations and other uses and applications of the subject invention will become apparent to those skilled in the art after considering this specification and the accompanying drawings, which disclose the preferred embodiments thereof. All such changes, modifications, variations and other uses and applications, which do not depart from the spirit and scope of the invention, are deemed to be covered by the invention, which is to be limited only by the claims, which follow.

1. A double-sided photovoltaic (PV) panel comprising:
a central thermal layer; and
at least two independent solar cell arrays attached on both sides of the central thermal layer, and externally facing portions of each of the at least two independent solar cell arrays being covered by a protection layer;
wherein the central thermal layer, the at least two independent solar cell arrays, and the protection layers are sandwiched together to form the double-sided photovoltaic (PV) panel.

2. The double-sided PV panel of claim 1, wherein the double sided PV panel is a single structure with a thickness of less than 5 mm.

3. The double-sided PV panel of claim 1, wherein each of the at least two independent solar cell arrays is encapsulated in a film of EVA (ethylene-vinyl acetate).

4. The double-sided PV panel of claim 1, wherein the protection layer is a glass layer, anti-reflective and made of tempered low iron glass.

5. The double-sided PV panel of claim 4, wherein a thickness of the glass layer is in between 2 to 3.2 mm.

6. The double-sided PV panel of claim 1, wherein the central thermal layer is an aluminium sheet or backing plate, for absorbing heat accumulated in the at least two independent solar cell arrays.

7. The double-sided PV panel of claim 6, wherein the central thermal layer comprises at least two aluminium sheets or backing plates.

8. The double-sided PV panel of claim 6, wherein the aluminium sheet or backing plate is coated with a dark shaded paint or an absorption assisting paint.

9. The double-sided PV panel of claim 1, wherein the double-sided PV panel further comprises a central support structure and a surrounding frame for supporting the double-sided PV panel.

10. The double-sided PV panel of claim 9, wherein the central support structure and the surrounding frame are made of aluminium.

11. The double-sided PV panel of claim 9, wherein movement or a tilt angle of the double-sided PV panel installed on the central support structure and the surrounding frame is controllable in real-time, for capturing direct solar rays and/or diffused light at all times and in all seasons.

12. The double-sided PV panel of claim 9, wherein the central support structure is configured to be installed on a rooftop.

13. The double-sided PV panel of claim 9, further comprising a cooling pipe located within the central thermal layer.

14. The double-sided PV panel of claim 13, wherein the surrounding frame further comprises a plurality of connectors coupled with the cooling pipe to enable water circulation through the cooling pipe, wherein the water circulation enabling cooling down of accumulated heat present on the double-sided PV panel during operation, and thereby eliminating formation of cracks or hotspots on the double-sided PV panel.

15. The double-sided PV panel of claim 13, wherein the cooling pipe is made of copper.

16. The double-sided PV panel of claim 1, wherein individual solar cells of the at least two independent solar cell arrays are sliced and connected as shingled solar cells partly overlapping each other.

17. A method of manufacturing a double-sided photovoltaic (PV) panel, the method comprising the steps of:
encapsulating a first and a second solar cell array each in between films of EVA (ethylene-vinyl acetate);
installing a thermal layer on inner portions of the first and second solar cell arrays;
providing a protection layer on an outer or externally facing portion of the first and second solar cell arrays; and
sandwiching together the first and second solar cell arrays, the thermal layer and the protection layer to form the double sided PV panel.

18. The method of claim 17, wherein a vacuum press is used for sandwiching together the first and second solar cell arrays, the backing plate and the glass layers.

19. The method of claim 17, further comprising installing the double-sided PV panel on a central support structure and a surrounding frame for supporting the double-sided PV panel during operation.

20. A method of operating a double sided PV panel, the method comprising the steps of:
providing a double sided panel as manufactured by the method of claim 17,
wherein movement or a tilt angle of the double-sided PV panel is controllable in real-time, for capturing direct solar rays and/or diffused light at all times and in all seasons.

21. (canceled)

22. (canceled)
